(19) United States
(12) Patent Application Publication
(10) Pub. No.: US 2026/0063841 A1
(43) Pub. Date: Mar. 5, 2026

(54) TUNABLE PHOTONIC OSCILLATOR FOR EFFICIENT FREQUENCY GENERATION

(71) Applicant: RTX BBN Technologies, Inc., Cambridge, MA (US)

(72) Inventor: Moe D. Soltani, Belmont, MA (US)

(21) Appl. No.: 18/818,287

(22) Filed: Aug. 28, 2024

(51) Int. Cl. G02B 6/12; G02B 6/293

(52) U.S. Cl. CPC G02B 6/12007; G02B 6/29338

(57) ABSTRACT

A frequency generator may include a coupled optical resonator coupled to a waveguide, where the coupled optical resonator includes three or more coupled individual resonators supporting three or more split-resonant frequencies distributed with a split-frequency spacing, and where the split-frequency spacing is determined by intracavity coupling between the three or more coupled individual resonators. The coupled optical resonator may receive pump light from the waveguide having optical frequencies corresponding to at least one of the three or more split-resonant frequencies and generates comb light having optical frequencies corresponding to the three or more split-resonant frequencies. A frequency generator may further include a photodetector, where the photodetector receives the comb light and generates an electrical signal having a frequency corresponding to the split-frequency spacing of the coupled optical resonator.

### TECHNICAL FIELD

The present disclosure relates generally to a frequency generator and, more particularly, to a tunable radio frequency generator incorporating a tunable photonic oscillator.

### BACKGROUND

Frequency generators may be used to generate electrical signals having controllable frequency components. Radio frequency (RF) generators that provide signals with frequencies in the RF spectral range may be particularly useful for a wide range of applications such as, but not limited to, communication systems, navigation systems, ranging systems (e.g., radar systems and variations thereof), measurement systems, or sensing systems. Many such applications are negatively impacted by phase noise and a lack of wide-range frequency tuning in a generated signal. However, achieving both low phase noise, wide frequency tuning, and a high signal strength remains a challenge.

### SUMMARY

In some embodiments, the techniques described herein relate to a frequency generator including a coupled optical resonator coupled to a waveguide, where the coupled optical resonator includes three or more coupled individual resonators supporting three or more split-resonant frequencies distributed with a split-frequency spacing determined by intracavity coupling between the three or more coupled individual resonators, where the coupled optical resonator receives pump light from the waveguide having optical frequencies corresponding to at least one of the three or more split-resonant frequencies and generates comb light having optical frequencies corresponding to the three or more split-resonant frequencies, where the comb light is coupled to the waveguide from the coupled optical resonator; and a photodetector, where the photodetector receives the comb light and generates an electrical signal having a frequency corresponding to the split-frequency spacing of the coupled optical resonator.

In some embodiments, the techniques described herein relate to a frequency generator, where the frequency of the electrical signal is tunable, where the coupled optical resonator further includes one or more phase shifters to tune the split-frequency spacing by controlling the intracavity coupling between the three or more coupled individual resonators.

In some embodiments, the techniques described herein relate to a frequency generator, where the electrical signal is a radio frequency (RF) signal.

In some embodiments, the techniques described herein relate to a frequency generator, where the three or more coupled individual resonators include at least one of traveling wave resonator or standing wave resonators.

In some embodiments, the techniques described herein relate to a frequency generator, where the coupled optical resonator includes a triply-coupled optical resonator, where the three or more split-resonant frequencies include a central split-resonant frequency and two sideband split-resonant frequencies, where the pump light corresponds to the central split-resonant frequency.

In some embodiments, the techniques described herein relate to a frequency generator, further including an optical modulator prior to the coupled optical resonator, where the optical modulator receives the pump light with an optical frequency corresponding to the central split-resonant frequency and generates sidebands in the pump light at optical frequences corresponding to the two sideband split-resonant frequencies.

In some embodiments, the techniques described herein relate to a frequency generator, where the coupled optical resonator reduces a phase noise between the central split-resonant frequency and the two sideband split-resonant frequencies in the comb light relative to the pump light from the optical modulator.

In some embodiments, the techniques described herein relate to a frequency generator, where the coupled optical resonator includes a quad-coupled optical resonator, where the three or more split-resonant frequencies include four split-resonant frequencies.

In some embodiments, the techniques described herein relate to a frequency generator, where the optical frequencies of the pump light are phase-locked and correspond to outer frequencies of the four split-resonant frequencies or inner frequencies of the four split-resonant frequencies.

In some embodiments, the techniques described herein relate to a frequency generation method including coupling pump light into a coupled optical resonator, where the coupled optical resonator includes three or more coupled individual resonators supporting three or more split-resonant frequencies distributed with a split-frequency spacing, where the split-frequency spacing is determined by intracavity coupling between the three or more coupled individual resonators; generating comb light with the coupled optical resonator, where the comb light includes optical frequencies corresponding to the three or more split-resonant frequencies; and illuminating a photodetector with the comb light to generate an electrical signal with a frequency corresponding to the split-frequency spacing.

In some embodiments, the techniques described herein relate to a frequency generation method, further including controlling the frequency of the electrical signal by generating control signals for one or more phase shifters in the coupled optical resonator, where the one or more phase shifters tune the split-frequency spacing by controlling the intracavity coupling between the three or more coupled individual resonators.

In some embodiments, the techniques described herein relate to a frequency generator including a coupled optical resonator, where the coupled optical resonator includes three or more coupled individual resonators supporting three or more split-resonant frequencies distributed with a split-frequency spacing, where the split-frequency spacing is determined by intracavity coupling between the three or more coupled individual resonators, where the coupled optical resonator includes one or more phase shifters to tune the split-frequency spacing by controlling the intracavity coupling between the three or more coupled individual resonators; at least one laser source to generate pump light having optical frequencies corresponding to at least one of the three or more split-resonant frequencies, where the coupled optical resonator receives the pump light and generates comb light having optical frequencies corresponding to the three or more split-resonant frequencies; a photodetector, where the photodetector receives the comb light and generates an electrical signal having a frequency corresponding to the split-frequency spacing of the coupled optical resonator; and a controller including one or more processors configured to execute program instructions causing the one or more processors to control the frequency of the electrical signal by generating control signals for the one or more phase shifters.

In some embodiments, the techniques described herein relate to a frequency generator, where the at least one laser source includes a laser oscillator.

In some embodiments, the techniques described herein relate to a frequency generator, where the electrical signal is a radio frequency (RF) signal.

In some embodiments, the techniques described herein relate to a frequency generator, where the three or more coupled individual resonators include at least one of traveling wave resonator or standing wave resonators.

In some embodiments, the techniques described herein relate to a frequency generator, where the coupled optical resonator includes a triply-coupled optical resonator, where the three or more split-resonant frequencies include a central split-resonant frequency and two sideband split-resonant frequencies, where the pump light corresponds to the central split-resonant frequency.

In some embodiments, the techniques described herein relate to a frequency generator, further including an optical modulator prior to the coupled optical resonator, where the optical modulator receives the pump light with an optical frequency corresponding to the central split-resonant frequency and generates sidebands in the pump light at optical frequences corresponding to the two sideband split-resonant frequencies.

In some embodiments, the techniques described herein relate to a frequency generator, where the coupled optical resonator reduces a phase noise between the central split-resonant frequency and the two sideband split-resonant frequencies in the comb light relative to the pump light from the optical modulator.

In some embodiments, the techniques described herein relate to a frequency generator, where the coupled optical resonator includes a quad-coupled optical resonator, where the three or more split-resonant frequencies include four split-resonant frequencies.

In some embodiments, the techniques described herein relate to a frequency generator, where the optical frequencies of the pump light are phase-locked and correspond to outer frequencies of the four split-resonant frequencies or inner frequencies of the four split-resonant frequencies.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1A illustrates a block diagram of a frequency generator, in accordance with one or more embodiments of the present disclosure.

FIG. 1B illustrates a frequency generator providing frequency tuning, in accordance with one or more embodiments of the present disclosure.

FIG. 1C illustrates a frequency generator including a triply-resonant coupled optical resonator with three coupled individual resonators, in accordance with one or more embodiments of the present disclosure.

FIG. 1D illustrates a frequency generator in which pump laser light includes three frequency peaks corresponding to split-resonant frequencies of a coupled optical resonator with three individual resonators, in accordance with one or more embodiments of the present disclosure.

FIG. 1E illustrates a frequency generator including a quad-resonant coupled optical resonator with four coupled individual resonators, in accordance with one or more embodiments of the present disclosure.

FIG. 2A illustrates a conceptual schematic of a coupled optical resonator with three individual resonators formed as ring resonators, in accordance with one or more embodiments of the present disclosure.

FIG. 2B illustrates a conceptual schematic of a coupled optical resonator with three individual resonators formed as racetrack resonators, in accordance with one or more embodiments of the present disclosure.

FIG. 2C illustrates coupling between two individual resonators having the design shown in FIG. 2B, in accordance with one or more embodiments of the present disclosure.

FIG. 3 illustrates a plot of spectral components of a frequency comb generated with a single resonator, in accordance with one or more embodiments of the present disclosure.

FIG. 4A illustrates a plot of split-resonant frequencies surrounding three exemplary modes of a triply-coupled coupled optical resonator, in accordance with one or more embodiments of the present disclosure.

FIG. 4B illustrates a plot of sets of four split-resonant frequencies surrounding three exemplary modes of a quad-coupled coupled optical resonator, in accordance with one or more embodiments of the present disclosure.

FIG. 5 is a flow diagram illustrating steps performed in a method for frequency generation, in accordance with one or more embodiments of the present disclosure.

### DETAILED DESCRIPTION

Reference will now be made in detail to the subject matter disclosed, which is illustrated in the accompanying drawings.

Before explaining one or more embodiments of the disclosure in detail, it is to be understood the embodiments are not limited in their application to the details of construction and the arrangement of the components or steps or methodologies set forth in the following description or illustrated in the drawings. In the following detailed description of embodiments, numerous specific details may be set forth in order to provide a more thorough understanding of the disclosure. However, it will be apparent to one of ordinary skill in the art having the benefit of the instant disclosure the embodiments disclosed herein may be practiced without some of these specific details. In other instances, well-known features may not be described in detail to avoid unnecessarily complicating the instant disclosure.

As used herein a letter following a reference numeral is intended to reference an embodiment of the feature or element that may be similar, but not necessarily identical, to a previously described element or feature bearing the same reference numeral (e.g., 1, 1a, 1b). Such shorthand notations are used for purposes of convenience only and should not be construed to limit the disclosure in any way unless expressly stated to the contrary.

Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of “a” or “an” may be employed to describe elements and components of embodiments disclosed herein. This is done merely for convenience and “a” and “an” are intended to include “one,” “one or more,” or “at least one,” and the singular also includes the plural unless it is obvious that it is meant otherwise.

Finally, as used herein any reference to “one embodiment” or “some embodiments” means that a particular element, feature, structure, or characteristic described in connection with the embodiment is included in at least one embodiment disclosed herein. The appearances of the phrase “in some embodiments” in various places in the specification are not necessarily all referring to the same embodiment, and embodiments may include one or more of the features expressly described or inherently present herein, or any combination of or sub-combination of two or more such features, along with any other features which may not necessarily be expressly described or inherently present in the instant disclosure.

Embodiments of the present disclosure are directed to systems and methods providing efficient generation of signals (e.g., electrical signals) with well-controlled frequencies and low phase noise. In some embodiments, the electrical signals include radio frequency (RF) signals with an RF frequency.

In some embodiments, an electrical signal at a desired frequency (e.g., an RF frequency, or any other desired frequency) is generated by illuminating a photodetector with comb light generated with a coupled optical resonator including three or more coupled individual resonators, where the comb light includes phase-locked frequency components separated by a split-frequency spacing (Ω) determined by intracavity coupling between the individual resonators, and where the frequency of the electrical signal is equal to this split-frequency spacing. For example, this electrical signal is generated by beating of the frequency components in the comb light in the photodetector (e.g., a high-speed photodetector). In this configuration, the comb light generated by the coupled optical resonator may have a limited set of optical frequency components at supported split-resonant frequencies separated by the split-frequency spacing. As an illustration, the coupled optical resonator may include a triply-coupled optical resonator providing three split-resonant frequencies, a quad-coupled optical resonator providing four split-resonant frequencies, or the like.

The frequency of the electrical signal may be tunable. In particular, this frequency may correspond to a split-frequency spacing of the comb light (e.g., a difference between successive phase-locked frequency components in the comb light), which may in turn be controlled by intracavity coupling between the individual resonators in the coupled optical resonator. As a result, the frequency of the electrical signal may be tuned by modifying a strength of the intracavity coupling between the cavities in the coupled optical resonator. For example, the coupled optical resonator may include one or more phase shifters in any of the individual resonators to adjust this intracavity coupling and thus the frequency of the electrical signal.

The coupled optical resonator may provide any split-frequency spacing such that the electrical signal generated by the photodetector may have any associated frequency. In some embodiments, the split-frequency spacing of the coupled optical resonator and thus the frequency of the electrical signal generated by the photodetector may fall within a radio frequency (RF) spectrum such that the electrical signal is an RF signal. As used herein, an RF signal may broadly include a signal having one or more frequency components in an RF spectrum, which may range from 3 kHz to 3 THz. In some embodiments, systems and methods disclosed herein provide the generation of RF signals in a range of 10 GHZ-20 GHz, 10 GHz-30 GHz, or any other suitable range. However, it is to be understood that the scope of the present disclosure is not limited to any particular frequency or frequency range.

The systems and methods disclosed herein may provide numerous benefits. For example, electro-optic conversion of a comb signal from an optical resonator into an electrical signal may beneficially provide low phase noise due to relatively high quality factors (Q) attainable using photonic integrated circuit (PIC) fabrication techniques. Further, the use of a coupled optical resonator (e.g., as opposed to a single-mode optical resonator with a single resonator) may enable precise control over both the number and separation of frequency peaks in the comb light to provide both power efficiency and low phase noise. As another illustration, generating a comb signal with frequency components separated by a split-frequency spacing of a coupled optical resonator beneficially decouples the frequency of the electrical signal from the FSR of an optical resonator, which may vary with frequency due to dispersion effects. Additionally, since the FSR is fundamentally linked to a physical size of an optical resonator, decoupling the frequency of the electrical signal from the FSR enables greater flexibility on designing the sizes of individual resonators.

In contrast, typical traveling-wave optical microresonators such as microrings can be used to generate radio frequency (RF) signals based on traditional optical frequency combs. In this case, the optical comb lines are generated due to the third order optical nonlinearity (also called Kerr nonlinearity) and a nonlinear four-wave mixing parametric oscillation process in the microresonator when a pump laser of certain power is launched to the resonator, and at certain resonator design condition (called appropriate resonator dispersion). The RF signal is generated by beating of the optical comb lines at a high-speed photodetectors, and the frequency of the RF signal is the frequency spacing between the optical comb lines that are determined by a free-spectral range (FSR) of the micro resonator. For a microresonator having a selected dispersion condition and selected resonance quality factor, light can be transmitted through the micro-resonator to generate a comb of optical signals that are equally spaced from each other by a frequency separation equal to the FSR of the micro-resonator. The combs are phase locked with each other. When the comb lines are received at a photodetector, their beat frequencies generate an RF signal at a frequency close to the FSR of the micro resonator. The phase noise of the RF signal is about four orders of magnitude smaller than the phase noise of the optical comb lines, due to the frequency division ratio between the optical frequency and the RF frequency.

However, there are several challenges to generating an RF signal from optical comb lines. First, optical comb lines are numerous, resulting in low optical power per comb line and a small amplitude of the RF signal. Second, the typical FSR of a micro-resonator (i.e., greater than about 100 GHz) requires a photodetector that can operate in this frequency range in order to detect the RF signal. Third, the pump laser power required with such a resonator to generate the optical comb lines is proportional to the perimeter of the resonator, which is inversely proportional to its FSR. For a resonator having a small FSR (e.g., about 10 GHZ), the corresponding perimeter of the resonator requires use of a high-power laser. Fourth, the resonator needs to be made of certain optical material and certain geometry dimensions to satisfy the dispersion condition for comb generation. Fifth, the comb frequency spacing in such a resonator is difficult to tune, thereby making it a challenge to make a tunable RF oscillator using these comb lines.

The systems and methods disclosed herein may beneficially reduce a number of optical comb lines generated by a resonator to increase the optical power per comb line for a given laser pump power, and consequently generate a higher-power electrical signal (e.g., a higher-power RF signal) at a split-resonant frequency. The systems and methods disclosed herein may further provide wide tuning of the frequency spacing between the optical comb lines (e.g., the split-resonant frequency) to generate a widely tunable oscillator (e.g., a widely-tunable RF oscillator).

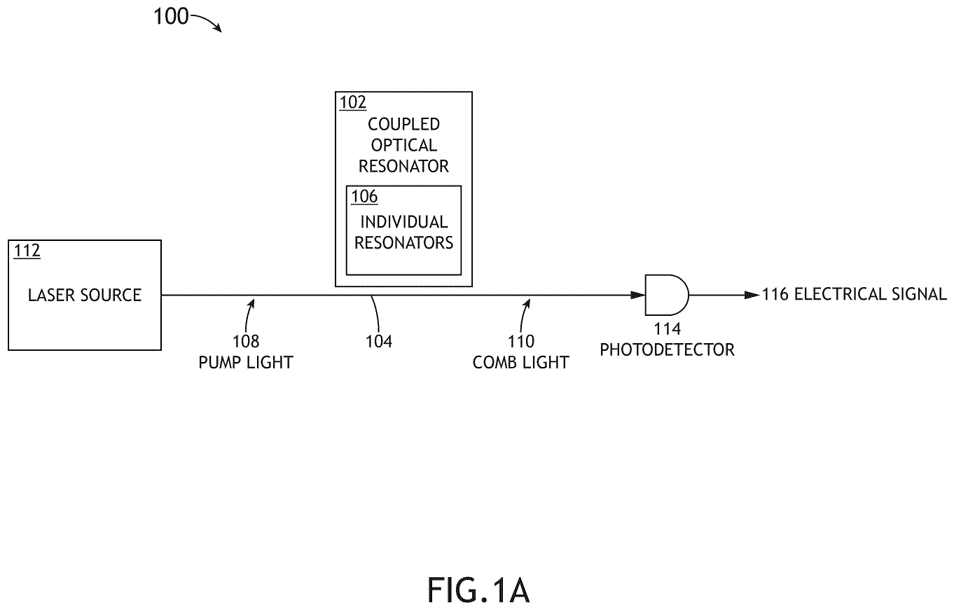

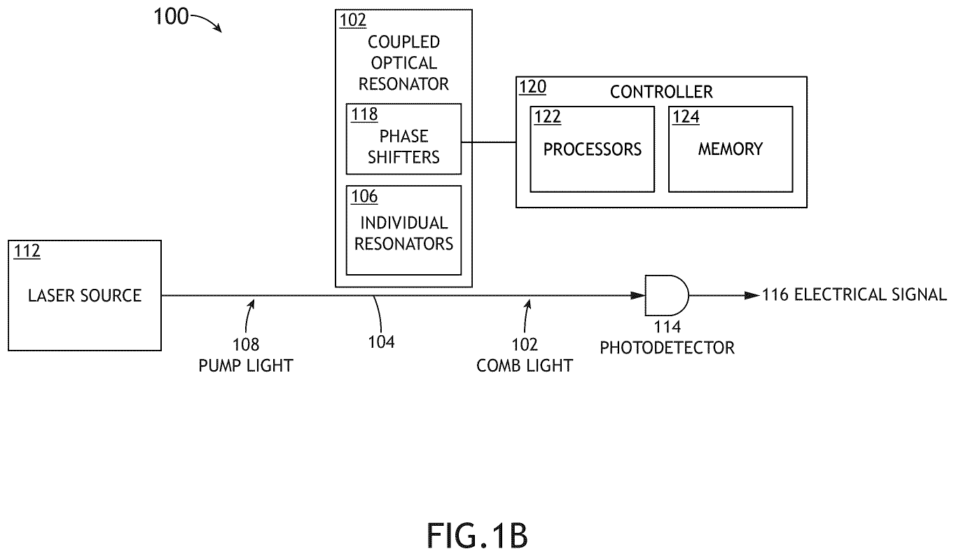

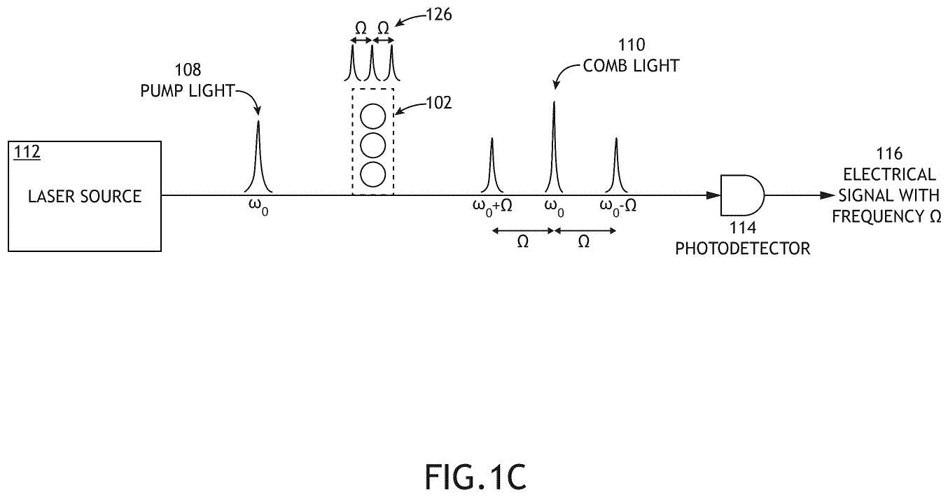

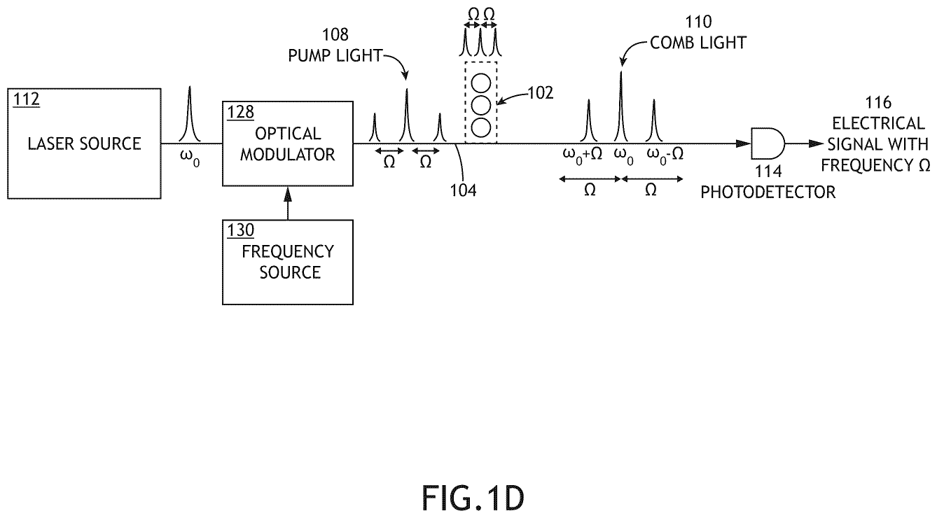

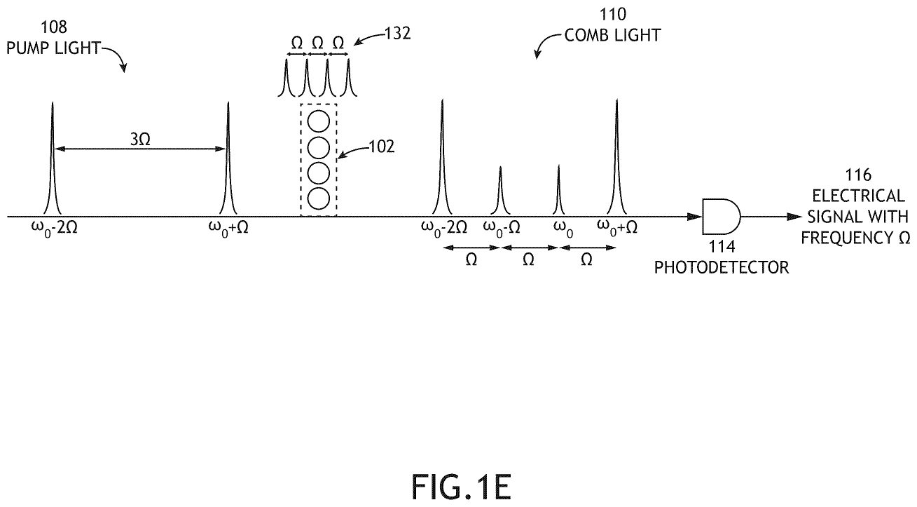

Referring now to FIGS. 1A-5, systems and methods providing efficient and stable frequency generation are described in greater detail, in accordance with one or more embodiments of the present disclosure.

FIG. 1A illustrates a block diagram of a frequency generator 100, in accordance with one or more embodiments of the present disclosure.

In some embodiments, the frequency generator 100 includes a coupled optical resonator 102 coupled to a waveguide 104, where the coupled optical resonator 102 includes three or more coupled individual resonators 106 supporting three or more split-resonant frequencies distributed with a split-frequency spacing determined by intracavity coupling between the individual resonators 106. The waveguide 104 may be any component suitable for guiding light including, but not limited to, a rib waveguide, a buried waveguide, or an optical fiber.

This coupled optical resonator 102 may receive pump laser light 108 and generate comb light 110 including optical frequencies corresponding to the split-resonant modes of the coupled optical resonator 102, where the frequency components of the comb light 110 are phase-locked and separated by the split-frequency spacing. For example, the pump laser light 108 may include optical frequencies corresponding to one or more of the split-resonant frequencies of the coupled optical resonator 102. Nonlinear optical processes such as, but not limited to, third-order optical nonlinearity (e.g., Kerr nonlinearity) and/or four-wave mixing in the coupled optical resonator 102 may then produce light at the optical frequencies associated with the various split-resonant frequencies. Further, the light at the split-resonant frequencies may have relatively low phase noise, particular when the coupled optical resonator 102 has a high quality factor (Q). In general, increasing the Q of the coupled optical resonator 102 reduces the phase noise, though phase noise may be limited by other factors including, but not limited to, quantum effects.

In some embodiments, the pump laser light 108 is generated by at least one laser source 112, which may be integrated into the frequency generator 100 or provided as an external component. The laser source 112 may include any type of laser oscillator known in the art such as, but not limited to, a diode laser source, a distributed feedback (DFB) laser, a distributed Bragg reflector (DBR) laser, or an external cavity laser (ECL). In some embodiments, the laser source 112 incorporates optical frequency stabilization to provide a consistent optical frequency (e.g., central optical frequency). The laser source 112 may further provide pump laser light 108 having any wavelength suitable for coupling with the coupled optical resonator 102. For example, the laser source 112 may provide pump laser light 108 having a wavelength associated with a selected split-resonant frequency of the coupled optical resonator 102 selected such that non-linear processes in the coupled optical resonator 102 may generate light at the other split-resonant frequencies.

In some embodiments, the frequency generator 100 includes a photodetector 114 coupled to the waveguide 104 to receive the comb light 110. The photodetector 114 may then generate an electrical signal 116 with a frequency equal to the split-frequency spacing of the comb light 110, which is associated with intracavity coupling of the individual resonators 106. For example, the electrical signal 116 may include a tone corresponding to a beat frequency equal to the split-frequency spacing of frequency peaks in the comb light 110. The frequency generator 100 may include any type of photodetector 114 suitable for generating the electrical signal 116 from incident comb light 110.

Various aspects of the coupled optical resonator 102 and the generation of comb light 110 are now described in greater detail, in accordance with one or more embodiments of the present disclosure.

The coupled optical resonator 102 may include three or more coupled individual resonators 106 of any type arranged to support three or more coupled split-resonant frequencies separated by a split-frequency spacing controlled by intracavity coupling between the individual resonators 106. For example, the split-resonant frequencies are associated with split resonant modes formed by intracavity coupling of these individual resonators 106. Further, the number of the coupled split-resonant frequencies may correspond to the number of resonators.

The individual resonators 106 may any type of resonating element (e.g., cavity) suitable for supporting split-resonant frequencies associated with intracavity coupling. In some embodiments, the individual resonators 106 are traveling wave resonators such as, but not limited to, ring resonators or racetrack resonators. In some embodiments, the individual resonators 106 are standing wave resonators such as, but not limited to Fabry-Perot resonators.

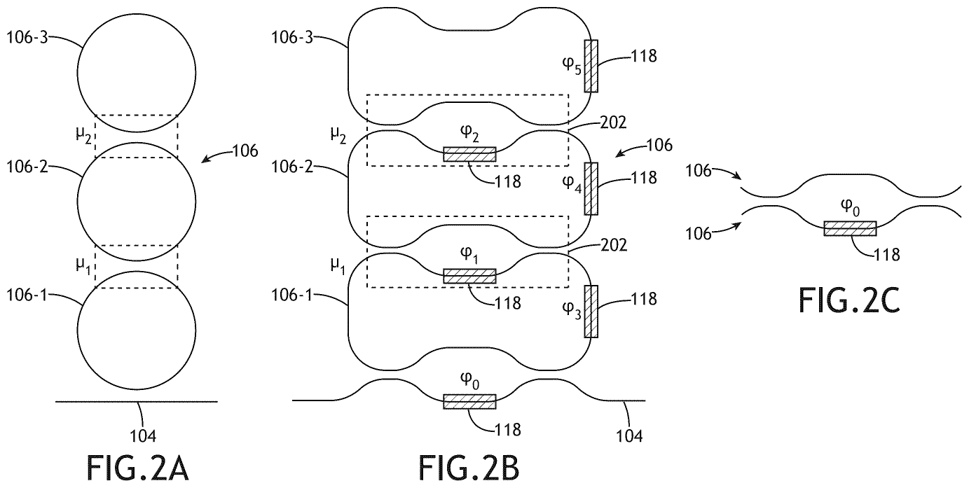

FIG. 2A illustrates a conceptual schematic of a coupled optical resonator 102 with three individual resonators 106 formed as ring resonators, in accordance with one or more embodiments of the present disclosure. In particular, FIG. 2A depicts a first individual resonator 106-1 coupled to the waveguide 104, a second individual resonator 106-2 coupled to the first individual resonator 106-1 (e.g., with a coupling coefficient μ₁), and a third individual resonator 106-3 coupled to the second individual resonator 106-2 (e.g., with a coupling coefficient μ₂).

FIG. 2B illustrates a conceptual schematic of a coupled optical resonator 102 with three individual resonators 106 formed as racetrack resonators, in accordance with one or more embodiments of the present disclosure. In a manner similar to FIG. 2A, FIG. 2B depicts a first individual resonator 106-1 coupled to the waveguide 104, a second individual resonator 106-2 coupled to the first individual resonator 106-1 (e.g., with a coupling coefficient μ₁), and a third individual resonator 106-3 coupled to the second individual resonator 106-2 (e.g., with a coupling coefficient μ₂).

The individual resonators 106 may have the same length (e.g., perimeter length) or may have different lengths so long as they support at least one common longitudinal mode. For example, an individual resonator 106 may generally support a series of longitudinal modes at optical frequencies w separated by a FSR, which is inversely related to its length. More generally, the FSR is related to a round-trip time of light through the resonator and is thus dependent on an optical path length of light in the individual resonator 106. As a result, the FSR is related to the group index or group velocity such that the FSR (and thus the frequency separation between any two particular frequency peaks) may be frequency-dependent in a dispersive medium. Taken together, coupling between two individual resonators 106 may occur for light with optical frequencies corresponding to any common longitudinal modes. The depictions in FIGS. 2A and 2B in which the individual resonators 106 have equal lengths is thus merely illustrative and is not limiting on the scope of the present disclosure.

In some embodiments, as depicted generally in FIGS. 1B and 1n the context of a racetrack resonator in FIG. 2B, the coupled optical resonator 102 includes one or more phase shifters 118 to control the phase of light throughout the individual resonators 106 (or the waveguide 104), which may be used to control the intracavity coupling between the individual resonators 106. For example, FIG. 2B depicts an induced phase ¢ for each of six illustrated phase shifters 118.

FIG. 2C illustrates coupling between two individual resonators 106 having the design shown in FIG. 2B, in accordance with one or more embodiments of the present disclosure. For example, FIG. 2C illustrations coupling regions shown the boxes 202 in FIG. 2B. In this configuration, the coupling coefficients μ_{1,2} may be related to phases φ_{1,2} induced by associated phase shifters 118 by the following expression:

$${μ}_{1 , 2} = F S R [ 1 - 2 k cos ( \frac{{ϕ}_{1 , 2}}{2} ) ] , \qquad ( 1 )$$

where FSR is the free spectral range of the individual resonators 106 and k is a coupling coefficient.

It is noted that the number and locations of the phase shifters 118 in FIGS. 2B-2C are merely illustrative and not limiting. In general, the coupled optical resonator 102 may include any number of phase shifters 118 (or zero phase shifters 118) at any locations suitable for providing desired coupling between the coupled optical resonator 102. Further, a coupling interface between the individual resonators 106 may have any design including, but not limited to, Mach-Zehnder interferometer.

FIG. 1B illustrates a frequency generator 100 providing frequency tuning, in accordance with one or more embodiments of the present disclosure.

In some embodiments, as shown in FIG. 1B, the frequency generator 100 includes a controller 120 to generate control signals to drive the phase shifters 118 and thus control intracavity coupling in the coupled optical resonator 102 and ultimately a frequency of an electrical signal 116 generated by the photodetector 114. The controller 120 may include one or more processors 122 configured to execute program instructions stored in memory 124 (e.g., a memory device), where the program instructions cause the processors 122 to implement one or more actions. The processors 122 may include any type of processing unit known in the art such as, but not limited to, one or more microprocessors, one or more digital signal processors (DSPs), one or more field-programmable gate array (FPGA) devices, one or more application-specific integrated circuits (ASICs), one or more central processing units (CPUs), or one or more graphical processing units (GPUs). The memory 124 may include any storage medium known in the art suitable for storing program instructions executable by the associated one or more processors 122. For example, the memory 124 may include a non-transitory memory medium. By way of another example, the memory 124 may include, but is not limited to, a read-only memory (ROM), a random-access memory (RAM), a magnetic or optical memory device (e.g., disk), a magnetic tape, a solid-state drive and the like.

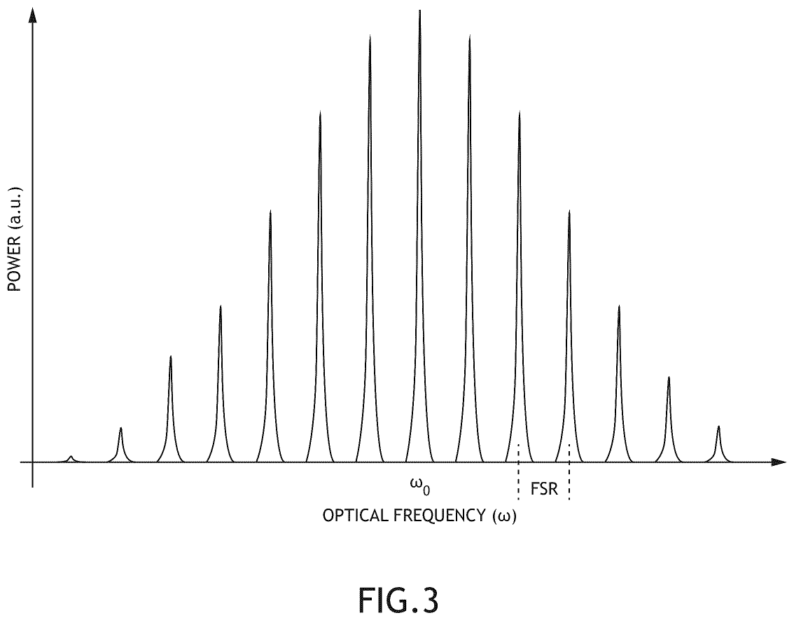

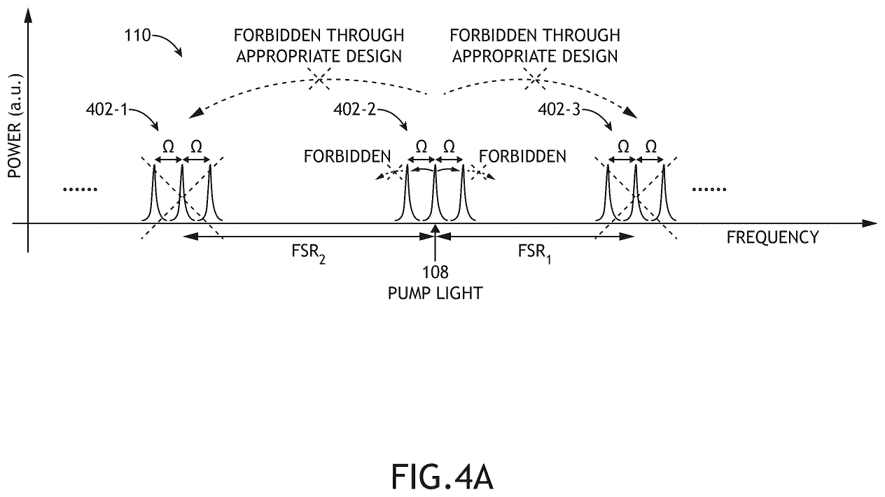

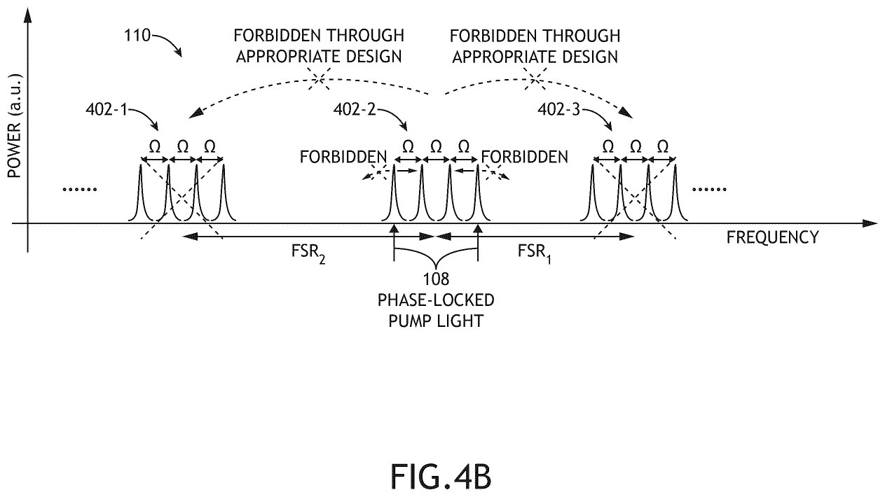

Referring now to FIGS. 3-4B, the control over the number and spacing of frequency peaks in comb light 110 is described in greater detail, in accordance with one or more embodiments of the present disclosure. In particular, FIG. 3 depicts the generation of a frequency comb with a single optical isolator, whereas FIGS. 4A-4B depicts the generation of comb light 110 with a coupled optical resonator 102.

The individual resonators 106 and the coupled optical resonator 102 more generally may be formed from any material or form factor. In some embodiments, the individual resonators 106 and the coupled optical resonator 102 are formed as a photonic integrated circuit using any suitable materials including, but not limited to, semiconductors, compound semiconductors, dielectric materials, or non-linear materials (e.g., non-linear crystals). As one non-limiting illustration, the individual resonators 106 may be formed from silicon nitride (SiN) on a base of silicon dioxide (SiO₂).

FIG. 3 illustrates a plot of spectral components of a frequency comb generated with a single optical resonator, in accordance with one or more embodiments of the present disclosure. As described above, an optical resonator may support a series of modes (e.g., which may be, but are not required to be, referred to as longitudinal modes) at optical frequencies separated by the FSR. As a result, coupling light with an optical frequency ω₀ corresponding to one of the modes may result in the generation of light at other supported modes through non-linear interactions within the optical resonator. For example, Kerr nonlinearity in the optical resonator can induce various nonlinear interactions such as, but not limited to four-wave mixing that may result in the conversion of input light to different optical frequencies. In general, the number of generated frequency peaks may depend on factors such as, but not limited to, phase matching conditions (which are a function of optical frequency, material dispersion, or the like), group velocity dispersion, or optical power in the input light.

It is recognized that directing light having frequency content as depicted in FIG. 3 to a photodetector may generate an electrical signal having a frequency corresponding to the FSR. However, such a configuration may have several drawbacks that may negatively impact some applications. First, the FSR is linked to the size of the optical resonator and thus provides little or no ability to tune the frequency of the electrical signal. Second, the FSR and thus the spacing between frequency peaks may vary, which may impact both phase matching and a bandwidth of the generated electrical signal. Third, the power of the electrical signal may be inversely related to the number of frequency peaks. As a result, certain configurations of material choice, FSR, and resonator size may lead to an undesirably large number of frequency peaks and thus an undesirably low signal power.

However, signal generation based a coupled optical resonator 102 as disclosed herein may provide efficient signal generation by limiting a number of frequency peaks and further provide tunable frequency selection based on intracavity coupling.

In some embodiments, a coupled optical resonator 102 generates split-resonant frequencies based on intracavity coupling between the constituent individual resonators 106.

As an illustration, a coupled optical resonator 102 formed as a triply-coupled resonator as shown in FIGS. 2A-2B may generate split-resonant frequencies around an input optical frequency ω₀ as follows:

$${ω}^{m} = {ω}_{0} + m \sqrt{{μ}_{1}^{2} + {μ}_{2}^{2}} , \qquad ( 2 )$$

$$m = - 1 , 0 , + 1 , \qquad ( 3 )$$

where m is a resonant mode number, μ₁ is a coupling coefficient between a first individual resonator 106-1 and a second individual resonator 106-2, and μ₂ is a coupling coefficient between a second individual resonator 106-2 and a third individual resonator 106-3. In this way, the triply-coupled individual resonators 106 may provide a triplet of split-resonant frequencies that are each separated by a split-frequency spacing

$$Ω = {ω}^{m + 1} - {ω}^{m} = \sqrt{{μ}_{1}^{2} + {μ}_{2}^{2}} .$$

It is to be understood that similar descriptions of split-resonant frequencies of a coupled optical resonator 102 with more than three coupled individual resonators 106 may be readily determined and that the coupled optical resonator 102 may generally have any number of coupled individual resonators 106 to generate any number of split-resonant frequencies.

These split-resonant frequencies may potentially surround any of the modes separated by the FSR of any of the individual resonators 106. However, in some embodiments, phase matching is only satisfied for a single set of split-resonant frequencies, which may constrain a number of frequency peaks in the comb light 110 and provide a high-power electrical signal at the split-resonant frequency Ω.

FIG. 4A illustrates a plot of split-resonant frequencies surrounding three exemplary modes of a triply-coupled coupled optical resonator 102, in accordance with one or more embodiments of the present disclosure. For example, FIG. 4A depicts three sets of split-resonant frequencies 402 (e.g., sets of triplet split-resonant frequencies labeled as 402-1, 402-2, and 402-3), where the sets of split-resonant frequencies 402 are separated by the FSR, and where the individual split-resonant frequencies 402 within each set are separated by a split-frequency spacing Ω. In FIG. 4A, the split-frequency spacing Ω between split-resonant frequencies in each set is constant, even if the value of the FSR and thus the separation between sets varies (e.g., due to dispersion). For example, FIG. 4A illustrates a first FSR value (FSR₁) between the set of split-resonant frequencies 402-2 and the set of split-resonant frequencies 402-3, along with a second FSR value (FSR₂) between the set of split-resonant frequencies 402-2 and the set of split-resonant frequencies 402-1.

In some embodiments, the coupled optical resonator 102 is designed to support light generation with frequencies corresponding to only a single set of split-resonant frequencies 402-2 around a single mode. For example, the coupled optical resonator 102 may be designed to provide that light generation within sets of split-resonant frequencies 402-1,402-3 around other modes have a low or negligible probability. In this way, the comb light 110 may have a limited number of frequency peaks corresponding to the number of split-resonant frequencies generated by intracavity coupling between individual resonators 106 in the coupled optical resonator 102. As an illustration, FIG. 4A illustrates how light generation within only the set of split-resonant frequencies 402-2 is supported, whereas the sets of split-resonant frequencies 402-1,402-3 are forbidden (e.g., group velocity dispersion of the coupled optical resonator 102 may be designed such that light conversion into such frequences is weak or non-existent).

Any properties of the coupled optical resonator 102 (or the constituent individual resonators 106) may be selected to provide light generation for only a single set of split-resonant frequencies around a single mode. For example, phase-matching conditions in the coupled optical resonator 102 may be governed by properties such as, but not limited to, the lengths of any of the individual resonators 106 (related to the FSR values of the individual resonators 106), shapes of the individual resonators 106, or material of the individual resonators 106 (related to nonlinearities that generate light at the split-resonant frequencies and/or dispersion in the individual resonators 106), any combination of which may be controlled to limit phase matching to a single set of split-resonant frequencies around a mode.

Further, as described previously herein, each set of split-resonant frequencies 402 may also have a constrained number of frequency peaks. For instance, comb light 110 from a triply-resonant coupled optical resonator 102 as described by Equations (2)-(3) may support only three frequency peaks. As a result, the comb light 110 may include a constrained number of frequency peaks associated with a single set of split-resonant frequencies 402 (e.g., determined by a number of the individual resonators 106), which may provide relatively high power at the split-frequency spacing Ω in the electrical signal 116 generated by the photodetector 114.

FIG. 1C illustrates a frequency generator 100 including a triply-resonant coupled optical resonator 102 with three coupled individual resonators 106, in accordance with one or more embodiments of the present disclosure. For example, the three individual resonators 106 in FIG. 1C may correspond to traveling wave resonators such as, but not limited to, those depicted in FIGS. 2A and 2B. Such a configuration may provide comb light 110 with three split-resonant frequencies corresponding to a single triplet of coherent optical frequencies that are phase locked. The inset 126 in FIG. 1C depicts the three split-resonant frequencies of the coupled optical resonator 102 separated by a split-frequency spacing Ω.

FIG. 1C further depicts a non-limiting configuration in which narrowband pump laser light 108 with an optical frequency ω₀ is coupled into the coupled optical resonator 102, where the optical frequency ω₀ corresponds to central split-resonant frequency of a triplet of split-resonant frequencies supported by the coupled optical resonator 102. The optical frequency ω₀ may further correspond to a longitudinal mode supported by the coupled optical resonator 102. In this configuration, the coupled optical resonator 102 may convert a portion of the pump laser light 108 at the optical frequency ω₀ to optical frequencies ω₀−Ω and ω₀+Ω associated with additional split-resonant frequencies to form a triplet via non-linear processes such as, but not limited to, Kerr nonlinearities and associated nonlinear processes. Further, these three split-resonant frequencies are the only supported modes (e.g., based on the selection of the lengths and materials forming the individual resonators 106) with non-negligible power such that the comb light 110 primarily or exclusively includes these three frequency peaks. It is noted that the frequency peaks in the comb light 110 may have any relative powers or intensities such that the depiction in FIG. 1B is merely illustrative and not limiting.

In some embodiments, the pump laser light 108 includes phase-locked frequency peaks associated with more than one split-resonant frequency supported by the coupled optical resonator 102. Such a configuration may reduce an amount of non-linear light generation required to generate the comb light 110 with a desired number of frequency peaks. Such a configuration may further utilize the coupled optical resonator 102 to reduce phase noise between frequency peaks in the pump laser light 108.

FIG. 1D illustrates a frequency generator 100 in which pump laser light 108 includes three frequency peaks corresponding to split-resonant frequencies of a coupled optical resonator 102 with three individual resonators 106, in accordance with one or more embodiments of the present disclosure. The phase-locked pump laser light 108 at the multiple split-resonant frequencies may be generated using any technique. In some embodiments, the frequency generator 100 includes an optical modulator 128 prior to the coupled optical resonator 102 to introduce phase-locked sidebands to incident light. As an illustration, FIG. 1D depicts a non-limiting configuration in which the frequency generator 100 includes an optical modulator 128 driven by a frequency source 130 with a frequency corresponding to the split-frequency spacing Ω. However, in some embodiments, light from two laser sources 112 is phase-locked using any phase locking technique known in the art.

The optical modulator 128 may receive pump laser light 108 with an optical frequency corresponding to a central split-resonant frequency ω₀ of the split-resonant frequency triplet and may generate sideband peaks at the other split-resonant frequencies ω₀−Ω, ω₀+Ω (e.g., at sideband split-resonant frequencies of the split-resonant frequency triplet). Each of these peaks in the pump laser light 108 may then be coupled into the coupled optical resonator 102. The resulting comb light 110 may further include these peaks. However, the coupled optical resonator 102 may reduce the phase noise present in the pump laser light 108 such that the comb light 110 may have lower phase noise than the pump laser light 108. In this way, the coupled optical resonator 102 coupled with the photodetector 114 may reduce or filter phase noise generated by the frequency source 130.

The optical modulator 128 may include any type of optical modulator known in the art suitable for generating sidebands based on the signal from the frequency source 130 such as, but not limited to, an electro-optical modulator (EOM). The frequency source 130 may include any frequency source known in the art providing the desired frequency 2 such as, but not limited to, a voltage-controlled oscillator (VCO) source.

Referring now to FIG. 1E, the generation of an electrical signal 116 with an optical modulator 128 with additional individual resonators 106 is described in greater detail, in accordance with one or more embodiments of the present disclosure.

FIG. 1E illustrates a frequency generator 100 including a quad-resonant coupled optical resonator 102 with four coupled individual resonators 106, in accordance with one or more embodiments of the present disclosure. The inset 132 in FIG. 1E depicts four split-resonant frequencies of the coupled optical resonator 102 separated by a split-frequency spacing Ω. In this configuration, the comb light 110 may have four frequency peaks associated with four split-resonant frequencies. As described with respect to FIG. 1C, the frequency peaks in the comb light 110 may have any relative powers or intensities such that the depiction in FIG. 1E is merely illustrative and not limiting.

In some embodiments, the pump laser light 108 may include two phase-locked frequencies associated with two of the split-resonant frequencies supported by the coupled optical resonator 102. The pump laser light 108 may include phase-locked frequencies associated with any two split-resonant frequencies of the coupled optical resonator 102 for which non-linear processes in the coupled optical resonator 102 (e.g., four-wave mixing, or the like) generate light at the remaining split-resonant frequencies.

As described with respect to FIG. 1D, two phase-locked frequencies may be generated using any technique known in the art. In some embodiments, the frequency generator 100 includes an optical modulator (not shown) to generate a phase-locked sideband at a desired frequency spacing from input light from a single laser source 112. In some embodiments, pump laser light 108 from two laser sources 112 is phase-locked using any phase-locking technique known in the art.

In some embodiments, as depicted in FIG. 1E, the pump laser light 108 includes two phase-locked frequencies corresponding to the outer split-resonant frequencies supported by the coupled optical resonator 102 (e.g., separated by 3Ω). In this configuration, nonlinear processes in the coupled optical resonator 102 such as, but not limited to, four-wave mixing may generate light at the inner two split-resonant frequencies. In some embodiments, the pump laser light 108 includes two phase-locked frequencies corresponding to the inner split-resonant frequencies supported by the coupled optical resonator 102 (e.g., separated by Ω). In this configuration, nonlinear processes in the coupled optical resonator 102 such as, but not limited to, four-wave mixing may generate light at the outer two split-resonant frequencies. In a general sense, pump laser light 108 may be provided at any of the split-resonant frequencies where non-linear processes in the coupled optical resonator 102 generate light at remaining split-resonant frequencies.

Further, as described with respect to the triply-resonant coupled optical resonator 102, a quad-resonant coupled optical resonator 102 may be designed such that phase matching is only satisfied for one set of split-resonant frequencies. FIG. 4B illustrates a plot of sets of four split-resonant frequencies surrounding three exemplary modes of a quad-coupled coupled optical resonator, in accordance with one or more embodiments of the present disclosure. FIG. 4B is substantially similar to FIG. 4A, except that FIG. 4B depicts four split-resonant frequencies surrounding the various modes separated by the FSR, which may vary as a function of optical frequency due to dispersion effects.

Referring now generally to FIGS. 1A-1E, the various illustrated components may be provided as a common system or as external elements. For example, the laser source 112 and/or the photodetector 114 may be integrated into the frequency generator 100 in some embodiments, but may be an external component in some embodiments. Further, any of the components may be provided in any form factor. In some embodiments, any or all of the components of the frequency generator 100 may be provided as photonic integrated circuit elements on one or more integrated chips.

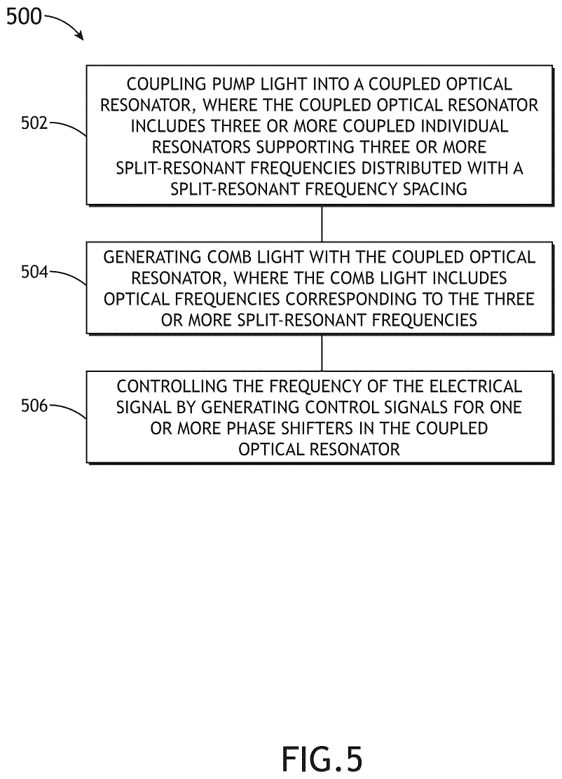

FIG. 5 is a flow diagram illustrating steps performed in a method 500 for frequency generation, in accordance with one or more embodiments of the present disclosure. The embodiments and enabling technologies described previously herein in the context of the frequency generator 100 should be interpreted to extend to the method 500. It is further noted, however, that the method 500 is not limited to the architecture of the frequency generator 100.

In some embodiments, the method 500 includes a step 502 of coupling pump laser light 108 into a coupled optical resonator 102, where the coupled optical resonator 102 includes three or more coupled individual resonators 106 supporting three or more split-resonant frequencies distributed with a split-frequency spacing. For example, the split-frequency spacing may be determined by intracavity coupling between the three or more coupled individual resonators 106.

In some embodiments, the method 500 includes a step 504 of generating comb light 110 with the coupled optical resonator 102, where the comb light 110 includes optical frequencies corresponding to the three or more split-resonant frequencies.

In some embodiments, the method 500 includes a step 506 of illuminating a photodetector 114 with the comb light 110 to generate an electrical signal 116 with a frequency corresponding to the split-frequency spacing.

In some embodiments, the method 500 includes a step 508 of controlling the frequency of the electrical signal 116 by generating control signals for one or more phase shifters 118 in the coupled optical resonator. For example, the one or more phase shifters 118 may tune the split-frequency spacing by controlling the intracavity coupling between the three or more coupled individual resonators 106.

Although the disclosure has been described with reference to the embodiments illustrated in the attached drawing figures, equivalents may be employed and substitutions made herein without departing from the scope of the claims. Components illustrated and described herein are merely examples of a system/device and components that may be used to implement embodiments of the disclosure and may be replaced with other devices and components without departing from the scope of the claims. Furthermore, any dimensions, degrees, and/or numerical ranges provided herein are to be understood as non-limiting examples unless otherwise specified in the claims.

What is claimed:

1. A frequency generator comprising:
a coupled optical resonator coupled to a waveguide, wherein the coupled optical resonator includes three or more coupled individual resonators supporting three or more split-resonant frequencies distributed with a split-frequency spacing determined by intracavity coupling between the three or more coupled individual resonators, wherein the coupled optical resonator receives pump light from the waveguide having optical frequencies corresponding to at least one of the three or more split-resonant frequencies and generates comb light having optical frequencies corresponding to the three or more split-resonant frequencies, wherein the comb light is coupled to the waveguide from the coupled optical resonator; and
a photodetector, wherein the photodetector receives the comb light and generates an electrical signal having a frequency corresponding to the split-frequency spacing of the coupled optical resonator.

2. The frequency generator of claim 1, wherein the frequency of the electrical signal is tunable, wherein the coupled optical resonator further comprises:
one or more phase shifters to tune the split-frequency spacing by controlling the intracavity coupling between the three or more coupled individual resonators.

3. The frequency generator of claim 1, wherein the electrical signal is a radio frequency (RF) signal.

4. The frequency generator of claim 1, wherein the three or more coupled individual resonators comprise:
at least one of traveling wave resonator or standing wave resonators.

5. The frequency generator of claim 1, wherein the coupled optical resonator comprises:
a triply-coupled optical resonator, wherein the three or more split-resonant frequencies comprise a central split-resonant frequency and two sideband split-resonant frequencies, wherein the pump light corresponds to the central split-resonant frequency.

6. The frequency generator of claim 5, further comprising:
an optical modulator prior to the coupled optical resonator, wherein the optical modulator receives the pump light with an optical frequency corresponding to the central split-resonant frequency and generates sidebands in the pump light at optical frequences corresponding to the two sideband split-resonant frequencies.

7. The frequency generator of claim 6, wherein the coupled optical resonator reduces a phase noise between the central split-resonant frequency and the two sideband split-resonant frequencies in the comb light relative to the pump light from the optical modulator.

8. The frequency generator of claim 1, wherein the coupled optical resonator comprises:
a quad-coupled optical resonator, wherein the three or more split-resonant frequencies comprise four split-resonant frequencies.

9. The frequency generator of claim 8, wherein the optical frequencies of the pump light are phase-locked and correspond to outer frequencies of the four split-resonant frequencies or inner frequencies of the four split-resonant frequencies.

10. A frequency generation method comprising:
coupling pump light into a coupled optical resonator, wherein the coupled optical resonator includes three or more coupled individual resonators supporting three or more split-resonant frequencies distributed with a split-frequency spacing, wherein the split-frequency spacing is determined by intracavity coupling between the three or more coupled individual resonators;
generating comb light with the coupled optical resonator, wherein the comb light includes optical frequencies corresponding to the three or more split-resonant frequencies; and
illuminating a photodetector with the comb light to generate an electrical signal with a frequency corresponding to the split-frequency spacing.

11. The frequency generation method of claim 10, further comprising:
controlling the frequency of the electrical signal by generating control signals for one or more phase shifters in the coupled optical resonator, wherein the one or more phase shifters tune the split-frequency spacing by controlling the intracavity coupling between the three or more coupled individual resonators.

12. A frequency generator comprising:
a coupled optical resonator, wherein the coupled optical resonator includes three or more coupled individual resonators supporting three or more split-resonant frequencies distributed with a split-frequency spacing, wherein the split-frequency spacing is determined by intracavity coupling between the three or more coupled individual resonators, wherein the coupled optical resonator includes one or more phase shifters to tune the split-frequency spacing by controlling the intracavity coupling between the three or more coupled individual resonators;
at least one laser source to generate pump light having optical frequencies corresponding to at least one of the three or more split-resonant frequencies, wherein the coupled optical resonator receives the pump light and generates comb light having optical frequencies corresponding to the three or more split-resonant frequencies;
a photodetector, wherein the photodetector receives the comb light and generates an electrical signal having a frequency corresponding to the split-frequency spacing of the coupled optical resonator; and
a controller including one or more processors configured to execute program instructions causing the one or more processors to control the frequency of the electrical signal by generating control signals for the one or more phase shifters.

13. The frequency generator of claim 12, wherein the at least one laser source comprises a laser oscillator.

14. The frequency generator of claim 12, wherein the electrical signal is a radio frequency (RF) signal.

15. The frequency generator of claim 12, wherein the three or more coupled individual resonators comprise:
at least one of traveling wave resonator or standing wave resonators.

16. The frequency generator of claim 12, wherein the coupled optical resonator comprises:
a triply-coupled optical resonator, wherein the three or more split-resonant frequencies comprise a central split-resonant frequency and two sideband split-resonant frequencies, wherein the pump light corresponds to the central split-resonant frequency.

17. The frequency generator of claim 16, further comprising:
an optical modulator prior to the coupled optical resonator, wherein the optical modulator receives the pump light with an optical frequency corresponding to the central split-resonant frequency and generates sidebands in the pump light at optical frequences corresponding to the two sideband split-resonant frequencies.

18. The frequency generator of claim 17, wherein the coupled optical resonator reduces a phase noise between the central split-resonant frequency and the two sideband split-resonant frequencies in the comb light relative to the pump light from the optical modulator.

19. The frequency generator of claim 12, wherein the coupled optical resonator comprises:
a quad-coupled optical resonator, wherein the three or more split-resonant frequencies comprise four split-resonant frequencies.

20. The frequency generator of claim 19, wherein the optical frequencies of the pump light are phase-locked and correspond to outer frequencies of the four split-resonant frequencies or inner frequencies of the four split-resonant frequencies.
